(19) United States
(12) Patent Application Publication
(10) Pub. No.: US 2013/0135923 A1
(43) Pub. Date: May 30, 2013

(54) PHASE CHANGE MEMORY DEVICE AND DATA STORAGE DEVICE HAVING THE SAME

(71) Applicant: Sun Hyuck YON, Icheon-si (KR)

(72) Inventor: Sun Hyuck YON, Icheon-si (KR)

(73) Assignee: SK HYNIX INC., Icheon-si (KR)

(21) Appl. No.: 13/599,592

(22) Filed: Aug. 30, 2012

(30) Foreign Application Priority Data
Nov. 25, 2011 (KR) 10-2011-0124595

(51) Int. Cl. G11C 11/21

(52) U.S. Cl. 365/163

(57) ABSTRACT

A phase change memory device includes a memory cell array including a plurality of memory cells each arranged at a region where a word line and a bit line cross each other, and a control logic including a reset program control logic configured to control a reset program operation for the plurality of memory cells and a set program control logic configured to control a set program operation for the plurality of memory cells.

### CROSS-REFERENCES TO RELATED APPLICATION

The present application claims priority under 35 U.S.C. §119(a) to Korean application number 10-2011-0124595, filed on Nov. 25, 2011, in the Korean Intellectual Property Office, which is incorporated by reference herein in its entirety.

### BACKGROUND

1. Technical Field

The present invention relates to a nonvolatile memory device, and more particularly, to a phase change memory device.

2. Related Art

In general, a semiconductor memory device is classified into a volatile memory device and a nonvolatile memory device. The volatile memory device loses data stored therein when power supply is cut off, but the nonvolatile memory device maintains data stored therein even though power supply is cut off. The nonvolatile memory device includes various types of memory cells.

Nonvolatile memory devices may be divided according to the structure of the memory cells comprising the device. For example, nonvolatile memory devices may be divided into a flash memory device, a ferroelectric RAM (FRAM) using a ferroelectric capacitor, a magnetic RAM (MRAM) using a tunneling magneto-resistive (TMR) layer, and a phase change memory device using chalcogenide alloys. In particular, the phase change memory device is a nonvolatile memory device using phase change, i.e., resistance change depending on temperature change. For this reason, the phase change memory device is also referred to as a variable-resistance memory device.

The memory cells of a phase change memory device are formed of a chalcogenide alloy which is a Ge—Sb—Te compound (GST) (hereafter, referred to as “GST material”), for example. The GST material has an amorphous state exhibiting relatively high resistivity and a crystalline state exhibiting relatively low resistivity. The memory cells of a phase change memory device may store data ‘1’ corresponding to the amorphous state and data ‘0’ corresponding to the crystalline state. The GST material of a phase change memory device is heated to program data corresponding to the amorphous state or crystalline state into the memory cells. For example, the amorphous state or crystalline state of the GST material may be controlled by adjusting the magnitude of a current for heating the GST material, or a time at which the current is applied.

An erase operation of a phase change memory device includes performing a program operation such that a memory cell has an amorphous state. The erase operation of a phase change memory device is typically performed in block units, in other words, the erase operation of a phase change memory device is typically performed on a memory block. For this reason, the erase operation of a phase change memory device requires quite a long time. In some cases, while an arbitrary block of a phase change memory device is erased, a program operation for the erased block and an arbitrary block belonging to another partition may be requested. In this case, the erase operation may be temporarily stopped. After the program operation is completed, the stopped erase operation is resumed.

The erase operation will be described in more detail as follows. FIG. 1 is a timing diagram schematically showing an erase operation of a conventional phase change memory device. Referring to FIG. 1, an erase operation for an arbitrary block included in a partition P0 is performed in response to an erase command ERA. When a suspend command SSPD is inputted to the phase change memory device while the erase operation is being performed, the erase operation is temporarily stopped. When a program command for the erased block and an arbitrary block belonging to another partition P1 is requested from outside, a program operation for the corresponding block is performed. When a resume command RSM is inputted to the phase change memory device from outside after the program operation is completed, the previously stopped erase operation is resumed.

In order to stop the erase operation, an operation of storing erase stop information such as address information is required. In order to resume the stopped erase operation, an operation of loading the erase stop information is also required. That is, in order to temporarily stop the erase operation and perform a program operation, an additional operation is required. This may serve as a factor that degrades the efficiency of the erase operation.

### SUMMARY

A phase change memory device capable of performing an erase operation efficiently and a data storage device having the same are described herein.

In one embodiment of the present invention, a phase change memory device includes: a memory cell array including a plurality of memory cells each arranged at a region where a word line and a bit line cross each other; and a control logic including a reset program control logic configured to control a reset program operation for the plurality of memory cells and a set program control logic configured to control a set program operation for the plurality of memory cells.

In another embodiment of the present invention, a phase change memory device includes: a memory cell array including a plurality of memory cells and divided into a first area and a second area; a control logic including a reset program control logic configured to control a reset program operation for the first area and the second area and a set program control logic configured to control a set program operation for the first area and the second area; and a write driver including: a first write driver configured to provide a program current to the first area according to a control signal of the reset program control logic or the set program control logic; and a second write driver configured to provide a program current to the second area according to a control signal of the reset program control logic or the set program control logic.

In another embodiment of the present invention, a data storage device includes a phase change memory device which includes a plurality of memory cells; and a control logic including a reset program control logic configured to control a reset program operation for the plurality of memory cells and a set program control logic configured to control a set program operation for the plurality of memory cells.

### BRIEF DESCRIPTION OF THE DRAWINGS

Features, aspects, and embodiments are described in conjunction with the attached drawings, in which:

FIG. 1 is a timing diagram schematically showing an erase operation of a conventional phase change memory device;

FIG. 2 is a block diagram illustrating a phase change memory device according to one embodiment;

FIG. 3 is a diagram illustrating a memory element of a memory cell of FIG. 2;

FIGS. 4 and 5 are circuit diagrams illustrating memory cells of FIG. 2;

FIG. 6 is a graph used for explaining properties of the phase change materials illustrated in FIGS. 4 and 5;

FIG. 7 is a block diagram illustrating a program control logic of the phase change memory device according to an embodiment;

FIG. 8 is a timing diagram schematically showing operations of the phase change memory device according to an embodiment;

FIG. 9 is a block diagram illustrating a data processing system including the phase change memory device according to an embodiment; and

FIG. 10 is a block diagram illustrating a computer system in which the data processing system of FIG. 9 is mounted.

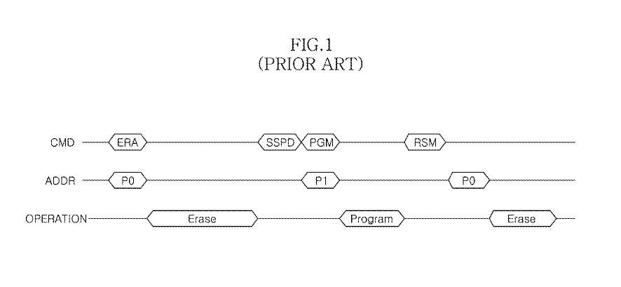

### DETAILED DESCRIPTION

Hereinafter, a phase change memory device and a data storage device having the same according to the present invention will be described below with reference to the accompanying drawings through example embodiments.

Example embodiments of the present invention will be described below in more detail with reference to the accompanying drawings. The present invention may, however, be embodied in different forms and should not be construed as limited to the embodiments set forth herein. Rather, these embodiments are provided so that this disclosure will convey a scope of the present invention to those skilled in the art.

The drawings are not necessarily to scale and in some instances, proportions may have been exaggerated in order to clearly illustrate features of the embodiments. In this specification, specific terms have been used. The terms are used to describe embodiments of the present invention, and are not used to qualify the sense or limit the scope of embodiments of the present invention.

In this specification, ‘and/or’ represents that one or more of components arranged before and after ‘and/or’ is included. Furthermore, ‘connected/coupled’ represents that one component is directly coupled to another component or indirectly coupled through another component. In this specification, a singular form may include a plural form as long as it is not specifically mentioned that the plural form is not included. Furthermore, ‘include/comprise’ or ‘including/comprising’ used in the specification represents that one or more components, steps, operations, and elements exists or are added.

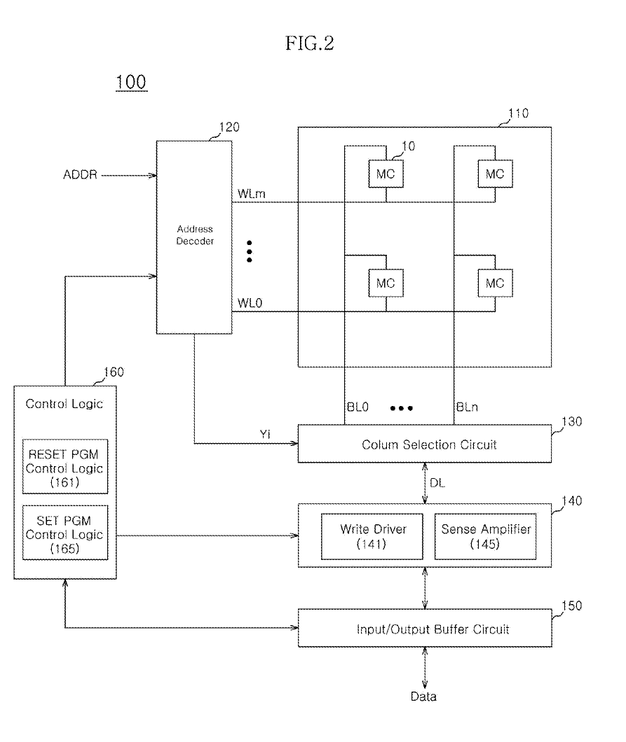

FIG. 2 is a block diagram illustrating a phase change memory device according to one embodiment. Referring to FIG. 2, the phase change memory device 100 includes a memory cell array 110, an address decoder 120, a column selection circuit 130, a data read/write circuit 140, an input/output buffer circuit 150, and a control logic 160.

The memory cell array 110 includes a plurality of memory cells arranged at intersections between bit lines BL0 to BLn and word lines WL0 to WLm. Each of the memory cells MC, for example memory cell 10, includes a phase change memory cell. For example, each of the memory cells MC may include a phase change memory cell having a memory element and a selecting element.

Each of the memory cells MC has different resistance values depending on a program state of a phase change material (that is, a GST material) forming the memory element. The program state is divided into an amorphous state exhibiting high resistivity and a crystalline state exhibiting low resistivity. The amorphous state defines a reset state, and the crystalline state defines a set state.

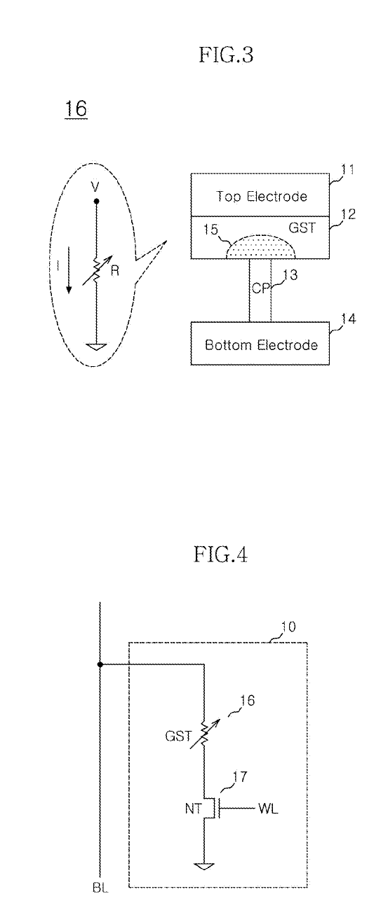

When the memory cell MC is in the amorphous state, it means that data ‘1’ is programmed in the memory cell MC, and when the memory cell MC has the crystalline state, it means that data ‘0’ is programmed in the memory cell MC. The memory cell MC will be described in detail with reference to FIGS. 3 to 5.

Meanwhile, the memory cell MC may have a plurality of intermediate states between the amorphous state and the crystalline state. Such a memory cell MC is referred to as a multi-level cell (MLC). The MLC may store 2-bit or more data.

The address decoder 120 is operated according to control of the control logic 160. The address decoder 120 is coupled to the memory cell array 110 through the word lines WL0 to WLm. The address decoder 120 is configured to decode an address ADDR inputted from outside. The address decoder 120 provides a bias voltage to a word line selected according to a decoding result. The address decoder 120 generates a column select signal Yi for selecting a bit line according to the decoding result. The generated column select signal Yi is provided to the column selection circuit 130.

The column selection circuit 130 is coupled to the memory cell array 110 through the bit lines BL0 to BLn. The column selection circuit 130 is configured to select a bit line in response to the column select signal Yi (i=0˜n) provided from the address decoder 120. The column selection circuit 130 is configured to electrically couple a data line DL and the bit line selected in response to the column select signal Yi.

The data read/write circuit 140 is operated according to the control of the control logic 160. The data read/write circuit 140 includes a write driver 141 and a sense amplifier 145.

The write driver 141 is configured to provide a program current to a bit line BL through the data line DL in response to a program pulse control signal. The program pulse control signal is provided from the control logic 160. The write driver 141 provides a reset current in response to a reset control signal, and provides a set current in response to a set control signal. The reset current is a current for changing a phase change material GST of a selected memory cell into the reset state. That is, the reset current is a current for programming data ‘1’ into the selected memory cell. The set current is a current for changing a phase change material GST of a selected memory cell into the set state. That is, the set current is a current for programming data ‘0’ into the selected memory cell.

The sense amplifier 145 is configured to read data stored in a selected memory cell during a read operation or program verify operation. The sense amplifier 145 senses a difference between the data line DL and a reference voltage, and performs a read operation.

The input/output buffer circuit 150 is configured to receive data from an external device (for example, a memory controller, a memory interface, a host or the like) or output data to the external device.

The control logic 160 is configured to control the overall operations of the phase change memory device 100 in response to a command provided from the external device. For example, the control logic 160 may control write, program (or write), and erase operations of the phase change memory device 100. Here, the erase operation indicates an operation of programming data such that a memory cell has the amorphous state.

The control logic 160 includes a reset program control logic 161 and a set program control logic 165. The reset program control logic 161 is configured to control a program operation into the reset state. That is, the reset program control logic 161 is configured to control the erase operation. The set program control logic 165 is configured to control a program operation into the set state. According to an embodiment of the present invention, the reset program operation may be performed by the reset program control logic 161, and the set program operation may be performed by the set program control logic 165. For this reason, the reset program operation, i.e., an erase operation may be performed regardless of whether a set program operation is simultaneously being performed. This indicates that the reset program operation and the set program operation may be processed in parallel (i.e., at the same time) for each partition of the memory cell array 110. Therefore, the erase operation of the phase change memory device may be performed efficiently.

FIG. 3 is a diagram used for explaining the memory element of the memory cell of FIG. 2. The memory cell of the phase change memory device 100 of FIG. 2 includes a memory element and a selecting element. FIG. 3 simply illustrates the memory element of the memory cell.

The memory element 16 has a variable resistance value depending on an applied current I. Therefore, the memory element 16 is referred to as a resistor element. As illustrated in a cross-sectional view of the memory element 16, the memory element 16 includes a top electrode 11, a phase change material (GST) 12, a contact plug (CP) 13, and a bottom electrode 14.

The top electrode 11 is coupled to a bit line BL. The bottom electrode 14 is coupled with the contact plug 13 and a selecting element (not illustrated). The contact plug 13 is formed of a conductive material (for example, TiN or the like). The contact plug 13 is referred to as a heater plug. The phase change material 12 is formed between the top electrode 11 and the contact plug 13.

The phase of the phase change material 12 is changed according to the magnitude of a supplied current or a time at which the current is supplied. The phase of the phase change material 12 corresponding to the reset state or the set state is decided by an amorphous volume 15 as illustrated in FIG. 3. As the phase progresses from the amorphous state to the crystalline state, the amorphous volume 15 decreases. The amorphous state corresponds to the reset state, and the crystalline state corresponds to the set state. The phase change material 12 has a resistance value which varies depending on the amorphous volume 15. That is, data to be written is decided by the amorphous volume 15 of the phase change material 12, which is formed according to the applied current.

FIGS. 4 and 5 are circuit diagrams illustrating the memory cells of FIG. 2. FIG. 4 illustrates a phase change memory cell including a MOS switch-type selecting element, and FIG. 5 illustrates a phase change memory cell including a diode switch-type selecting element.

Referring to FIG. 4, the memory cell 10 includes a memory element 16 and a selecting element 17. The memory element 16 is coupled between a bit line BL and the selecting element 17. The selecting element 17 is coupled between the memory element 16 and a ground GND. The selecting element 17 has a gate coupled to a word line WL. FIG. 4 illustrates that the memory element 16 is coupled between the bit line BL and the selecting element 17, but in some embodiments the selecting element 17 may be coupled between the bit line BL and the memory element 16.

The memory element 16 has the same configuration as the memory element described in FIG. 3 and performs the same operation. Therefore, further detailed descriptions thereof are omitted herein.

The selecting element 17 includes an NMOS transistor NT. When a predetermined voltage is applied to the word line WL in order to select the memory cell 10, the NMOS transistor NT is turned on. When the NMOS transistor NT is turned on, the memory element 16 receives a current through the bit line BL.

Referring to FIG. 5, the memory cell 10 includes a memory element 16 and a selecting element 18. The memory element 16 is coupled between a bit line BL and the selecting element 18. The selecting element 18 is coupled between the memory element 16 and a word line WL.

The memory element 16 has the same configuration as the memory element described in FIG. 3 and performs the same operation. Therefore, further detailed descriptions thereof are omitted herein.

The selecting element 18 includes a diode D. The anode of the diode D is coupled to the memory element 16, and the cathode of the diode D is coupled to the word line WL. When a ground voltage GND is applied to the word line WL in order to select the memory cell 10, a voltage difference between the anode and the cathode of the diode D is changed. When the voltage difference between the anode and the cathode of the diode D becomes higher than the threshold voltage of the diode D, the diode D is turned on. When the diode D is turned on, the memory element 16 receives a current through the bit line BL.

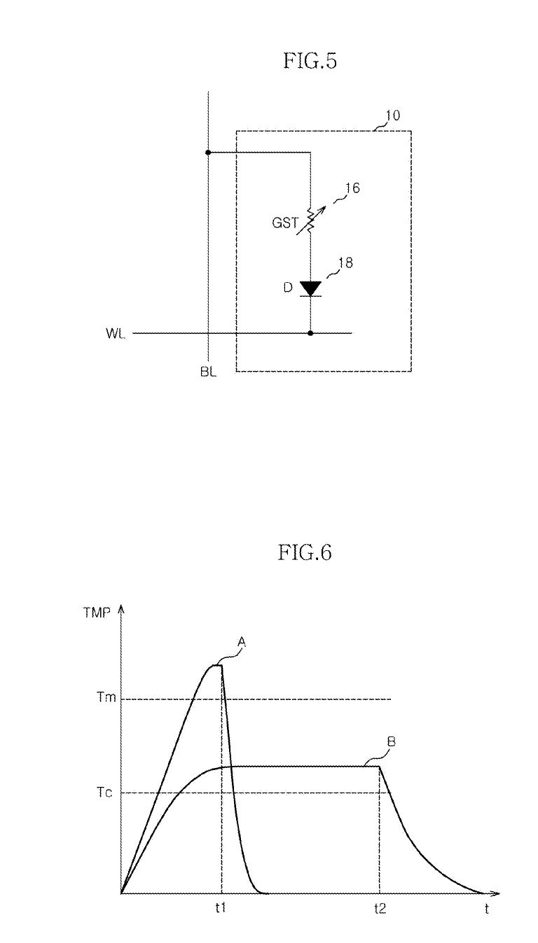

FIG. 6 is a graph used for explaining properties of the phase change materials illustrated in FIGS. 4 and 5. In FIG. 6, symbol ‘A’ indicates a condition where the phase change material GST changes into the amorphous state, i.e., the reset state, and symbol ‘B’ indicates a condition where the phase change material GST changes into the crystalline state, i.e., the set state.

When the phase change material GST is rapidly quenched after being heated at a higher temperature than a melting temperature Tm for a time t1, the phase change material GST changes into the amorphous state. When the phase change material GST changes into the amorphous state, the memory cell 10 stores data ‘1’. On the other hand, when the phase change material GST is slowly quenched after being heated at a temperature higher than a crystallization temperature Tc for a time t2 which is longer than the time t1, the phase change material GST changes into the crystalline state. Here, the crystallization temperature Tc is lower than the melting temperature Tm. When the phase change material GST changes into the crystalline state, the memory cell 10 stores data ‘0’.

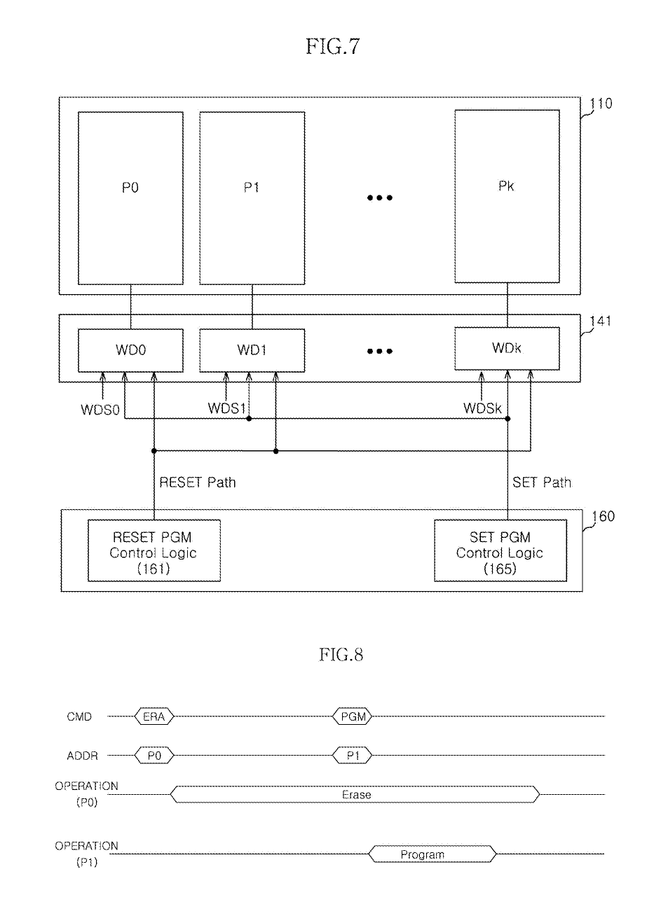

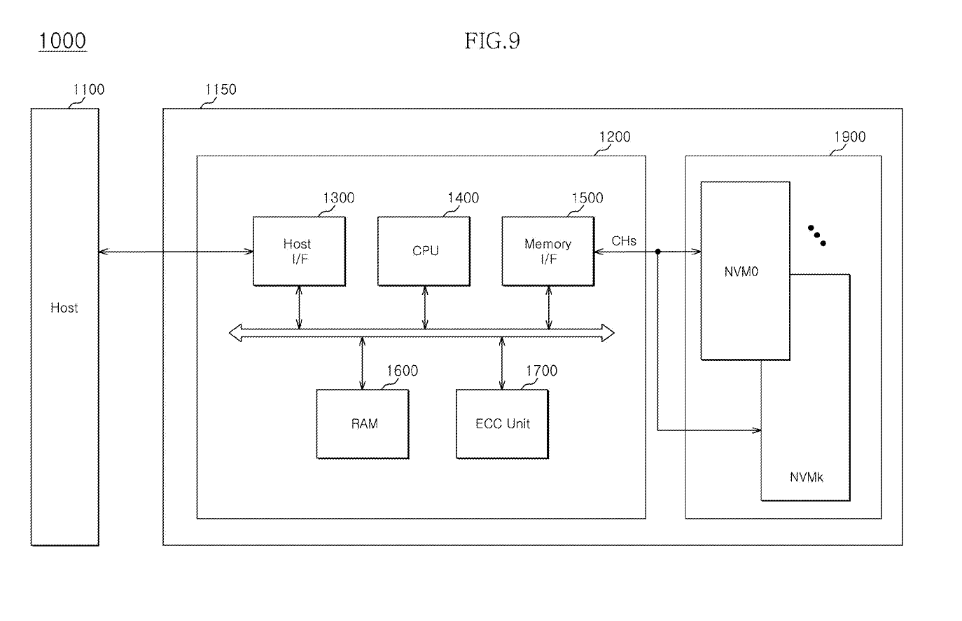

FIG. 7 is a block diagram explaining program control logic of the phase change memory device according to an embodiment. FIG. 8 is a timing diagram schematically showing operations of the phase change memory device according to an embodiment. Hereafter, referring to FIGS. 7 and 8, the program operation and the erase operation of the phase change memory device will be described in detail.

The memory cell array 110 includes a plurality of areas or partitions P0 to Pk. Here, a partition indicates a group of memory blocks. That is, a partition includes a plurality of memory blocks. As is well known, each of the memory blocks includes a plurality of memory cells.

The write driver 141 includes a plurality of write drivers WD0 to WDk. The write drivers WD0 to WDk each correspond to a respective partitions P0 to Pk. The respective write drivers WD0 to WDk perform a program operation on a corresponding partitions P0 to Pk. For example, the write driver WD0 is configured to provide a program current to the corresponding partition P0 in response to a program pulse control signal received from the control logic 160. In a more general example, the respective write drivers WD0 to WDk are configured to provide a program current to the corresponding partitions P0 to Pk in response to a program pulse control signal of the control logic 160.

The control logic 160 includes the reset program control logic 161 and the set program control logic 165. A control signal of the reset program control logic 161, for example, a program pulse control signal is provided to the write drivers WD0 to WDk through a reset path. A control signal of the set program control logic 165, for example, a program pulse control signal, is provided to the write drivers WD0 to WDk through a set path.

As described above, the reset program control logic 161 controls the program operation into the reset state. That is, the reset program control logic 161 controls the erase operation. The set program control logic 165 controls the program operation into the set state. This means that the reset program operation (that is, the erase operation) and the set program operation may be processed in parallel. This will be described in more detail as follows.

In FIG. 8, it is assumed that the first partition P0 and the second partition P1 are selected and operated by an address ADDR. Furthermore, it is assumed that a reset program operation (that is, erase operation) for an arbitrary block included in the first partition P0 and a set program operation for a memory cell included in the second partition P1 are requested from an outside source.

The reset program control logic 161 controls a reset program operation (that is, erase operation) for an arbitrary block included in the first partition P0. At this time, the control signal of the reset program control logic 161 may be provided only to the first write driver WD0 according to a write driver select signal WDS0 for enabling the first write driver WD0. The write driver select signal WDS0 may be provided to the first write driver WD0 based on the address ADDR.

While the arbitrary block included in the first partition P0 is reset (that is, erased), a program command for a memory cell included in the second partition P1 may be requested from an outside source. In this case, while the arbitrary block of the first partition P0 is reset (that is, erased), a program operation for the second partition P1 is performed. That is, the set program control logic 165 controls a set program operation for a memory cell of an arbitrary block included in the second partition P1. At this time, a control signal of the set program control logic 165 may be provided to the second write driver WD1 according to a write driver select signal WDS1 for enabling the second write driver WD1. Similarly, the write driver select signal WDS1 may be provided to the second write driver WD1 based on an address.

The phase change memory device 100 of FIG. 2 according to an embodiment of the present invention includes the reset program control logic 161 and the set program control logic 165 which are separately provided. Therefore, the reset program operation (that is, erase operation) and the set program operation of memory cells may be performed in parallel for each partition.

Meanwhile, in this embodiment of the present invention, it has been described that, during a reset program operation of a specific partition (that is, during an erase operation), a set program operation of another partition is performed. However, it will be easily understood that various operations on another partition may also be performed. For example, during a reset program operation of a specific partition (that is, during an erase operation), a read operation of another partition may be simultaneously performed.

FIG. 9 is a block diagram illustrating a data processing system including the phase change memory device according to an embodiment. Referring to FIG. 9, the data processing system 1000 includes a host 1100 and a data storage device 1150. The data storage device 1150 includes a controller 1200 and a data storage medium 1900.

The controller 1200 is coupled to the host 1100 and the data storage medium 1900. The controller 1200 is configured to access the data storage medium 1900 in response to a request from the host 1100. For example, the controller 1200 is configured to control a read, program, or erase operation of the data storage medium 1900. The controller 1200 is configured to drive firmware for controlling the data storage medium 1900.

The controller 1200 includes a host interface 1300, a central processing unit (CPU) 1400, a memory interface 1500, a RAM 1600, and an error correction code (ECC) unit 1700, which are well-known components.

The CPU 1400 is configured to control overall operations of the controller 1200. The RAM 1600 may be used as a working memory of the CPU 1400.

The host interface 1300 is configured to interface the host 1100 and the controller 1200. For example, the host interface 1300 may be configured to communicate with the host 1300 through one of various interface protocols such as a USB (Universal Serial Bus) protocol, an MMC (Multimedia Card) protocol, a PCI (Peripheral Component Interconnection) protocol, a PCI-E (PCI-Express) protocol, a PATA (Parallel Advanced Technology Attachment) protocol, a SATA (Serial ATA) protocol, an SCSI (Small Computer Small Interface) protocol, and an IDE (Integrated Drive Electronics) protocol.

The memory interface 1500 is configured to interface the controller 1200 and the data storage medium 1900. The data storage medium 1900 may be implemented with the phase change memory devices 100 of FIG. 2 according to an embodiment of the present invention. The data storage medium 1900 may include a plurality of phase change memory devices NVM0 to NVMk. As the data storage medium 1900 are implemented with the phase change memory devices 100 according to an embodiment of the present invention, the operation speed of the data storage device 1150 may be increased.

The ECC unit 1700 may be configured to detect and correct an error of data read from the data storage medium 1900.

The controller 1200 and the data storage medium 1900 may form a solid state drive (SSD).

As another example, the controller 1200 and the data storage medium 1900 may be integrated into one semiconductor device, thereby forming a memory card. For example, the controller 1200 and the data storage medium 1900 may be integrated into one semiconductor device, thereby forming a PCMCIA (personal computer memory card international association) card, a CF (compact flash) card, a smart media card, a memory stick, a multi-media card (MMC, RS-MMC, or MMC-micro), a SD (secure digital) card (SD, Mini-SD, or Micro-SD), or a UFS (universal flash storage) card.

As another example, the controller 1200 or the data storage medium 1900 may be mounted in various types of packages. For example, the controller 1200 or the data storage medium 1900 may be packaged and mounted according to various methods such as POP (package on package), ball grid arrays (BGAs), chip scale package (CSP), plastic leaded chip carrier (PLCC), plastic dual in-line package (PDIP), die in waffle pack, die in wafer form, chip on board (COB), ceramic dual in-line package (CERDIP), plastic metric quad flat package (MQFP), thin quad flat package (TQFP), small outline IC (SOIC), shrink small outline package (SSOP), thin small outline package (TSOP), thin quad flat package (TQFP), system in package (SIP), multi chip package (MCP), wafer-level fabricated package (WFP), and wafer-level processed stack package (WSP).

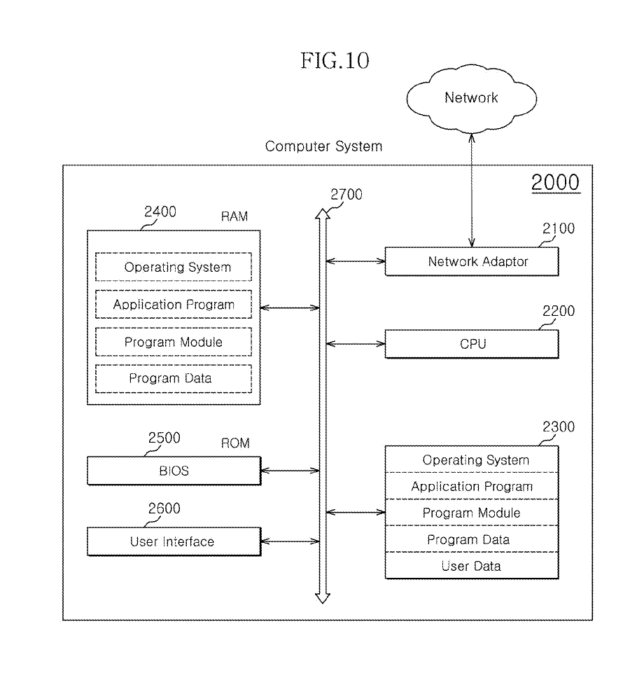

FIG. 10 is a block diagram illustrating a computer system in which the data processing system of FIG. 9 is mounted. Referring to FIG. 10, the computer system 2000 includes a network adaptor 2100, a CPU 2200, a data storage device 2300, a RAM 2400, a ROM 2500, and a user interface 2600, which are electrically coupled to a system bus 2700. Here, the data storage device 2300 may be implemented with the data storage device 1150 of FIG. 9.

The network adaptor 2100 is configured to provide an interface between the computer system 2000 and external networks. The CPU 2200 is configured to perform overall arithmetic operations for driving an operating system or application programs staying in the RAM 2400.

The data storage device 2300 is configured to store overall data required by the computer system 2000. For example, the data storage device 2300 stores the operating system for driving the computer system 2000, application programs, various program modules, program data, and user data.

The RAM 2400 may be used as a working memory device of the computer system 2000. During booting, the operating system, the application programs, and the various program modules, which are read from the data storage device 2300, and program data required for driving the programs are loaded into the RAM 2400. The ROM stores a basic input/output system (BIOS) which is activated before the operation system is driven. Through the user interface 2600, information is exchanged between the computer system 2000 and a user.

In addition, the computer system 2000 may further include a battery or modem. Furthermore, although not illustrated in the drawing, application chipsets, a camera image process (CIS) and the like may be further included in the computer system 2000.

According to an embodiment of the present invention, the erase operation of the phase change memory device may be efficiently performed.

While certain embodiments have been described above, it will be understood to those skilled in the art that the embodiments described are by way of example only. Accordingly, the phase change memory devices and the data storage devices described herein should not be limited based on the described embodiments. Rather, the phase change memory devices and the data storage devices described herein should only be limited in light of the claims that follow when taken in conjunction with the above description and accompanying drawings.

What is claimed is:

1. A phase change memory device comprising:
a memory cell array comprising a plurality of memory cells each arranged at a region where a word line and a bit line cross each other; and
a control logic comprising a reset program control logic configured to control a reset program operation for the plurality of memory cells and a set program control logic configured to control a set program operation for the plurality of memory cells.

2. The phase change memory device according to claim 1, wherein the reset program control logic and the set program control logic are configured to perform a program operation in parallel.

3. The phase change memory device according to claim 2, wherein while the reset program control logic controls a reset program operation for any one of the plurality of memory cells, the set program control logic simultaneously controls a set program operation for any one of the other plurality of memory cells.

4. The phase change memory device according to claim 3, wherein each of the plurality of memory cells comprises:
a memory element having a first end coupled to the bit line and formed of a phase change material; and
a selecting element configured to select the memory element.

5. The phase change memory device according to claim 4, wherein the selecting element comprises a MOS transistor coupled between a second end of the memory element and a ground, and having a gate coupled to the word line.

6. The phase change memory device according to claim 4, wherein the selecting element comprises a diode coupled between a second end of the memory element and the word line.

7. A phase change memory device comprising:
a memory cell array comprising a plurality of memory cells and divided into a first area and a second area;
a control logic comprising a reset program control logic configured to control a reset program operation for the first area and the second area, and a set program control logic configured to control a set program operation for the first area and the second area; and
a write driver comprising:
a first write driver configured to provide a program current to the first area according to a control signal of the reset program control logic or the set program control logic; and
a second write driver configured to provide a program current to the second area according to a control signal of the reset program control logic or the set program control logic.

8. The phase change memory device according to claim 7, wherein while the reset program control logic controls a reset program operation for the first area through the first write driver, the set program control logic simultaneously controls a set program operation for the second area through the second write driver.

9. The phase change memory device according to claim 8, wherein the reset program operation for the first area and the set program operation for the second area are performed in parallel.

10. The phase change memory device according to claim 7, wherein the control signal of the reset program control logic is commonly provided to the first write driver and the second write driver through a reset path, the control signal of the set program control logic is commonly provided to the first write driver and the second write driver through a set path, and
the first write driver and the second write driver are configured to selectively receive any one of the control signal of the reset program control logic and the control signal of the set program control logic according to a write driver select signal.

11. The phase change memory device according to claim 10, wherein the write driver select signal is provided to the first write driver and the second write driver based on an address.

12. The phase change memory device according to claim 7, wherein each of the memory cells comprises:
a memory element formed of a phase change material; and
a selecting element configured to select the memory element.

13. A data storage device comprising:
a phase change memory device comprising:
a plurality of memory cells; and
a control logic comprising a reset program control logic configured to control a reset program operation for the plurality of memory cells and a set program control logic configured to control a set program operation for the plurality of memory cells.

14. The data storage device according to claim 13, wherein the reset program control logic and the set program control logic are configured to perform a program operation in parallel.

15. The data storage device according to claim 13, wherein while the reset program control logic controls a reset program operation for any one of the plurality of memory cells, the set program control logic simultaneously controls a set program operation for any one of an other of the plurality of memory cells.

16. The data storage device according to claim 13, wherein the phase change memory device and a controller form a memory card.

17. The data storage device according to claim 13, wherein the phase change memory device and a controller form a solid state drive (SSD).
